(19) United States
(12) Patent Application Publication
(10) Pub. No.: US 2007/0077757 A1
(43) Pub. Date: Apr. 5, 2007

(54) Method of forming metal wiring in semiconductor device

(76) Inventor: Cheon Man Shim, Seoul (KR)

Correspondence Address: MCKENNA LONG & ALDRIDGE LLP;Song K. Jung, 1900 K Street, N.W., Washington, DC, 20006, US

(21) Appl. No.: 11/320,773

(22) Filed: Dec. 30, 2005

(30) Foreign Application Priority Data
Oct. 5, 2005 (KR) 10-2005-0093466

(51) Int. Cl. H01L 21/44

(52) U.S. Cl. 438/672; 438/675; 257/E21.577

(57) ABSTRACT

A method of forming a metal wiring in a semiconductor device includes forming a lower wiring layer, forming an etch stopping film and an interlayer insulation film, forming a photo-resist pattern, forming a via-hole using the photo-resist pattern as a mask, ashing the photo-resist pattern, cleaning the via-hole, etching a portion of the etch stopping film exposed through the via-hole to expose the lower wiring layer, and burying a metallic material in the via-hole to provide a via-contact. Photo-resist residues or particles that remain after the ashing process can be perfectly removed or substantially perfectly removed through a cleaning process to open a lower metal wiring layer. It is possible to prevent the upper and lower metal wiring layers from inappropriately making contact with each other because the lower metal wiring layer is perfectly opened due to the absence of photo-resist residues.

This application claims the benefit of Korean Patent Application No. 10-2005-0093466, filed on Oct. 5, 2005, which is hereby incorporated by reference for all purposes as if fully set forth herein.

### BACKGROUND OF THE INVENTION

1. Field of the Invention

The present invention relates to a method of fabricating a semiconductor device, and more particularly, to a method of forming a metal wiring in a semiconductor device.

2. Discussion of the Related Art

The development of semiconductor technologies has enabled the integration of as much as 1×10⁹ devices into a chip having the size of a fingernail. In order to accommodate high integration and high speed semiconductor devices, studies have been made in the materials field and the semiconductor chip structure field. With respect to the semiconductor chip structure field, metal layers are increasingly used and an STI method is widely used to isolate devices on a substrate. With respect to the materials field, copper and low dielectric constant (low-k) materials have been used.

Particularly, as semiconductor devices are highly integrated, gaps between metal wirings become narrower, so that the need for a multi-layer wiring structure has increased. In s multi-layer wiring structure, parasitic capacitance and resistance, existing between adjacent metal wirings on one or different layers, become important. Technologies related to forming multi-layer wirings having smaller parasitic capacitance and resistance have been focused on providing a highly-integrated semiconductor device having a high operation speed.

In order to provide a metal wiring having smaller parasitic capacitance and resistance, it is necessary to use a low resistivity material such as copper or a low dielectric constant material such as a low-k insulation film. Particularly, copper is advantageous because it can be obtained with a low cost, does not significantly burden to a manufacturing process, and has low resistivity. Furthermore, copper can resist to electro-migration phenomenon unlike aluminum.

A damascene process is typically used to form a copper wiring pattern because it is difficult to form a copper wiring pattern through an etching process. Damascene processes can be classified into single damascene processes and dual damascene processes.

In a single damascene process, a via-hole is formed by using a photo-resist pattern as a mask. The photo-resist pattern is then removed through an ashing process. Then, a portion of an etch stopping film exposed through the via-hole is removed to expose a metal wiring in a lower layer. The exposed metal wiring in a lower layer is connected to another metal wiring in an upper layer.

In a dual damascene process, a via-hole is formed by using a first photo-resist pattern as an etching mask. A trench is then formed by using a second photo-resist pattern as an etching mask. Then, the photo-resist patterns are removed through an ashing process, and the portion of the etch stopping film exposed through the via-hole and the trench is etched to expose a metal wiring in a lower layer. The exposed metal wiring in the lower layer is connected to another metal wiring in an upper layer.

A related art method of forming a metal wiring in a semiconductor device will be described with reference to the accompanying drawings.

FIGS. 1A through 1E are cross-sectional views of a semiconductor device made by a method of forming a metal wiring in a semiconductor device according to a related art single damascene process. FIGS. 2A through 2G are cross-sectional views of a semiconductor device made by a method of forming a metal wiring in a semiconductor device according to a related art dual damascene process.

In a related art single damascene process, as shown in FIG. 1A, an etch stopping layer 12 is deposited on a semiconductor substrate having a lower metal wiring layer 11, and an interlayer insulation film 13 is formed as a thick layer on the etch stopping layer 12.

In addition, a photo-resist is deposited on the interlayer insulation film 13, and patterned through a exposure process and a development process to provide a photo-resist pattern 14 on which a via-hole portion is opened.

Then, the interlayer insulation film 13 is etched using the photo-resist pattern 14 as an etching mask to form a via-hole 16. As a result, the etch stopping film 12 is exposed through the via-hole 16.

As shown in FIG. 1B, the photo-resist pattern 14 is removed. A dry etching is usually used in an ashing process for removing the photo-resist pattern 14. In this process, the photo-resist pattern 14 may not be perfectly removed. Thus, unwanted residues or particles 15 are generated and remain.

As shown in FIGS. 1C and 1D, a portion of the etch stopping film 12 exposed through the via-hole 16 is etched to open the lower metal wiring layer 11. Then, a cleaning process is performed to remove residues of the etch stopping film 12, which are generated in the etching process for the etch stopping film 12.

As shown in FIG. 1E, a metallic material 17 is filled in the via-hole 16 using a gap-filling process, and an over-filled portion of the metallic material 17 is removed to provide a via-contact that makes contact with the lower metal wiring layer 11. Thus, the lower metal wiring layer 11 is electrically connected to the upper metal wiring layer through the via-contact.

On the other hand, in a related art dual damascene process, as shown in FIG. 2A, an etch stopping layer 52 is deposited on a semiconductor substrate having a lower metal wiring layer 51. An interlayer insulation film 53 is formed as a thick layer on the etch stopping layer 52.

In addition, a photo-resist is deposited on the interlayer insulation film 53, and a photo-resist pattern 54 is formed through a diffraction exposure process and a development process. A patterning process is performed so that the photo-resist pattern 54 has an intermediate step through the diffraction exposure process, while a portion of the photo-resist corresponding to a via-hole is entirely removed to open the interlayer insulation film 53. A portion corresponding to a trench has an intermediate step, and remaining portions of the photo-resist are retained.

Then, the interlayer insulation film 53 is etched using the photo-resist pattern 54 as an etching mask to provide the via-hole 56. The etch stopping film 52 is exposed through the via-hole 56.

As shown in FIG. 2B, an ashing process is performed on the photo-resist pattern 54 until the intermediate step of the photo-resist pattern 54 is entirely removed to expose the interlayer insulation film 53. Unwanted residues or particles 59 are generated and remain on the interlayer insulation film 53. Then, as shown in FIG. 2C, the interlayer insulation film 53 is etched within a predetermined thickness by using the photo-resist pattern as an etching mask to form a trench 57.

As shown in FIG. 2D, an ashing process for removing the photo-resist pattern 54 is performed. In this process, the photo-resist pattern 54 is seldom perfectly removed and unwanted residues or particles 55 are generated and remain on the interlayer insulation film 53.

As shown in FIGS. 2E and 2F, a portion of the etch stopping film 52 exposed through the via-hole 56 is etched to open the lower metal wiring layer 51. Then, a cleaning process is performed to substantially perfectly remove residues of the etch stopping film 52, that may be generated during the etching of the etch stopping film 52.

As shown in FIG. 2G, a metallic material 77 is filled in the via-hole 56 and the trench 57 to make contact with the lower metal wiring layer 51 through the via-hole 56. An overfilled portion of the metallic material 77 is removed to provide a via-contact and an upper metal wiring layer that make contact with the lower metal wiring layer 51. Thus, the lower metal wiring layer 51 is electrically connected to the upper metal wiring layer through the via- contact.

However, the aforementioned related art methods of forming a metal wiring in a semiconductor device have following problems.

When a damascene process is applied to form a via-hole for connecting a lower metal wiring layer to the upper metal wiring layer, it is critical that a portion of the etch stopping film exposed through via hole is removed in order to expose the lower metal wiring layer. However, organic residues, remnants or particles of the photo-resist may remain even after an ashing process for removing the photo-resist pattern.

Thus, the etch stopping film may not be entirely removed because of the presence of the residues or particles of the photo-resist remaining in the via-hole. The lower metal wiring layer therefore may not be appropriately exposed. Thus, the upper and lower metal wiring layers can not appropriately make contact with each other, and this may cause reduction in a manufacturing yield.

### SUMMARY OF THE INVENTION

Accordingly, the present invention is directed to a method of forming a metal wiring in a semiconductor device that substantially obviates one or more problems due to limitations and disadvantages of the related art.

An advantage of the present invention is to provide a method, in which residues or particles generated during an ashing of a photo-resist are perfectly removed or substantially perfectly removed through a cleaning process before a portion of the etch stopping film inside a via-hole is removed to open a lower metal wiring layer.

Another advantage of the present invention is to provide a method, in which it is possible to perfectly open a lower metal wiring layer in the etching of an etch stopping film.

Another advantage of the present invention is to provide a method in which an upper metal wiring layer perfectly makes contact with a lower metal wiring layer.

Additional features and advantages of the invention will be set forth in the description which follows, and will be apparent from the description, or may be learned by practice of the invention. The objectives and other advantages of the invention will be realized and attained by the method particularly pointed out in the written description and claims hereof as well as the appended drawings.

To achieve these and other advantages and in accordance with the purpose of the present invention, as embodied and broadly described, a method of forming a metal wiring in a semiconductor device includes forming a lower wiring layer on a semiconductor substrate, forming an etch stopping film and an interlayer insulation film on an entire surface of the semiconductor substrate including the lower wiring layer, forming a photo-resist pattern on the interlayer insulation film, forming a via-hole by using the photo-resist pattern as a mask, ashing the photo-resist pattern, cleaning the via-hole, etching a portion of the etch stopping film exposed through the via-hole to expose the lower wiring layer, and burying a metallic material in the via-hole to provide a via-contact.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIGS. 1A-1E are cross-sectional views of a semiconductor device made by a method of forming a metal wiring in a semiconductor device according to a related art single damascene process;

FIGS. 2A-2G are cross-sectional views of a semiconductor device made by a method of forming a metal wiring in a semiconductor device according to a related art dual damascene process;

FIGS. 3A-3E are cross-sectional views of a semiconductor device made by a method of forming a metal wiring in a semiconductor device according to a single damascene process of the present invention;

FIGS. 4A-4H are cross-sectional views of a semiconductor device made by a method of forming a metal wiring in a semiconductor device according to a dual damascene process of the present invention;

FIG. 5 is a graph for comparing manufacturing yields of an SRAM having a trench formed according to a related art technique and having a trench formed according to the present invention; and

FIGS. 6A and 6B are transmission electron microscope (TEM) photographs showing a dual damascene structure when optimized and unoptimized cleanings are respectively performed for a Cu/low-k device having a thickness of 0.13 μm.

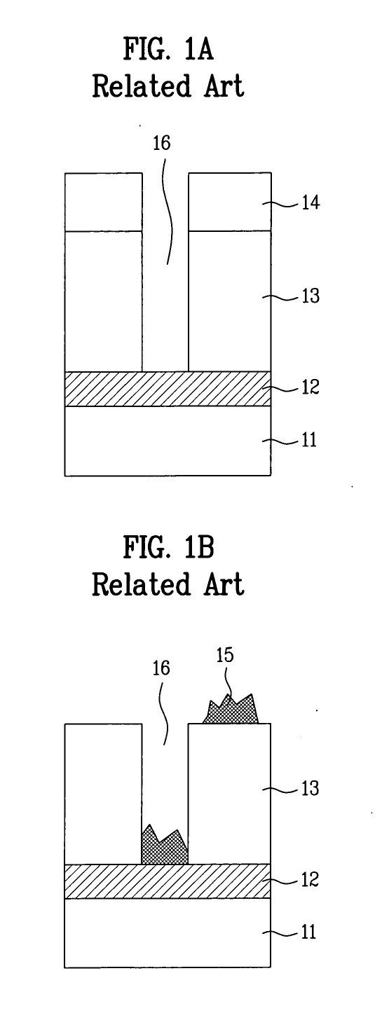

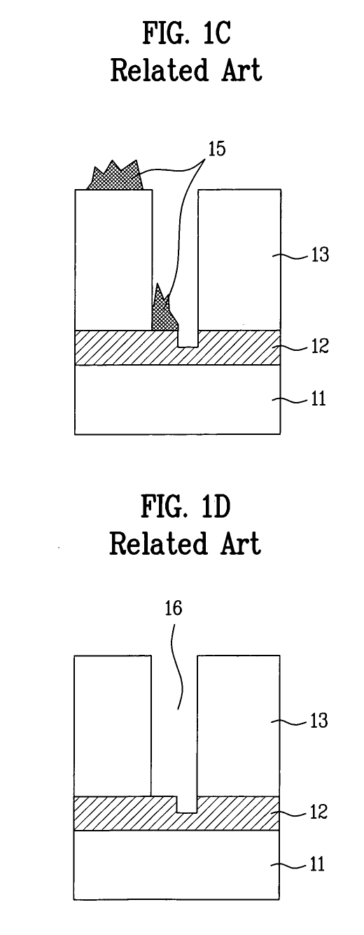

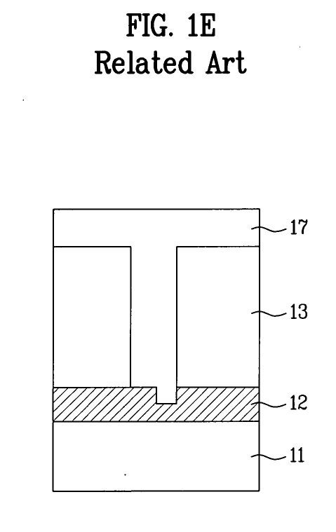

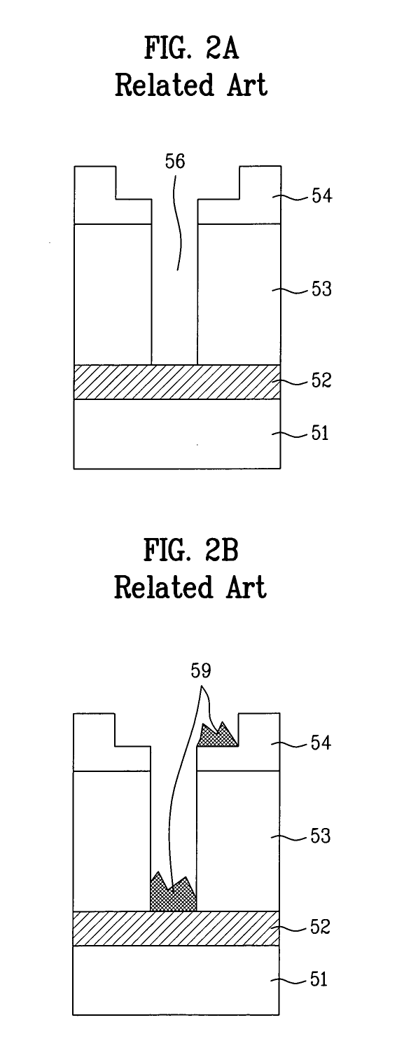

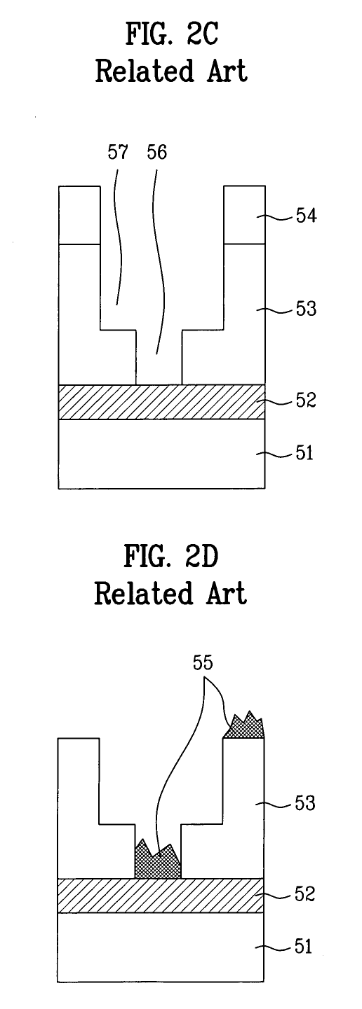

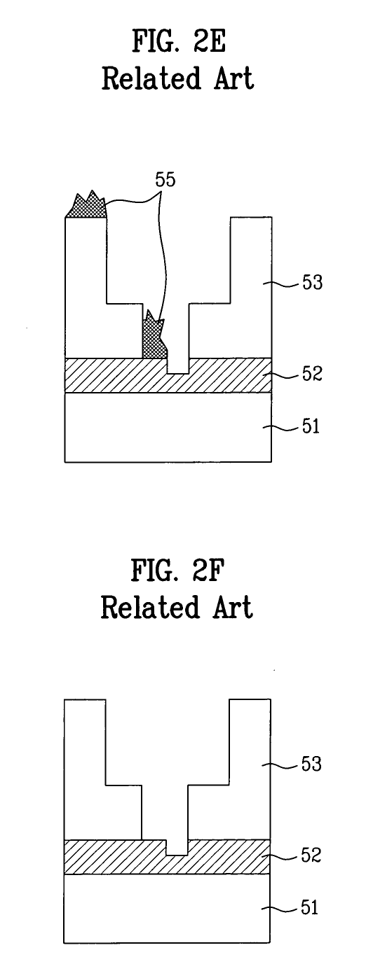

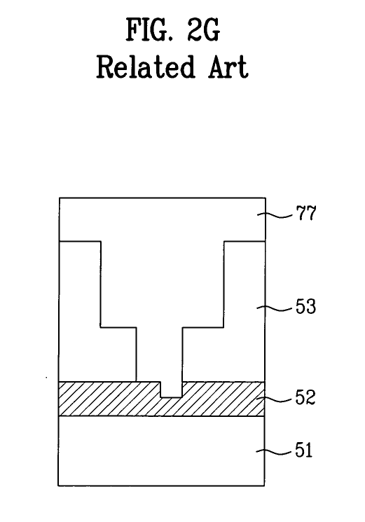

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

First Exemplary Embodiment

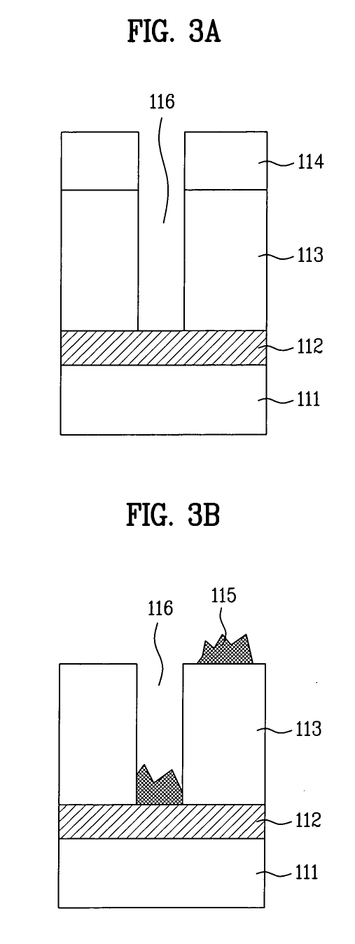

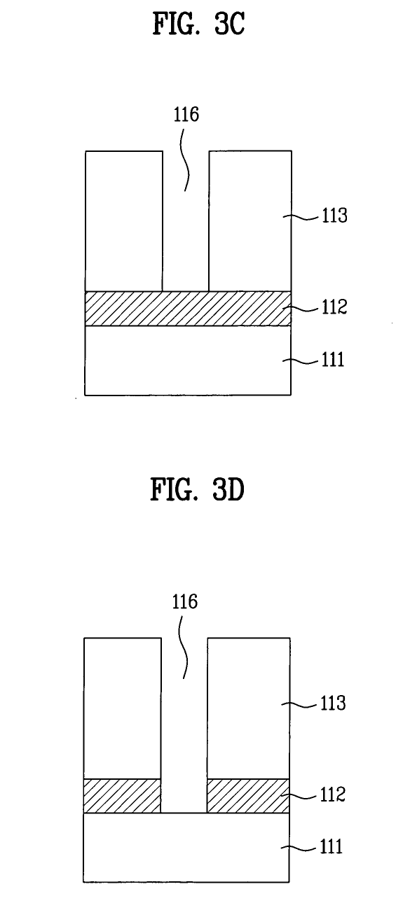

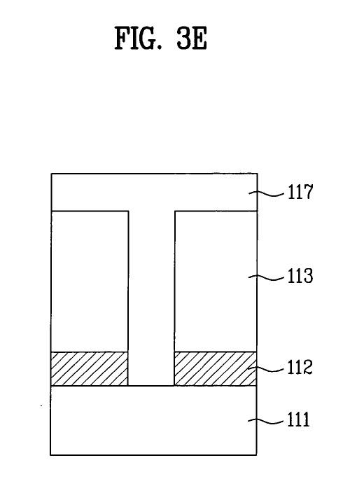

FIGS. 3A-3E are cross-sectional views of a semiconductor device made by a method of forming a metal wiring in a semiconductor device according to a single damascene process of the present invention.

The first exemplary embodiment relates to a single damascene process according to the present invention. Specifically, as shown in FIG. 3A, an etch stopping film 112 is deposited on a semiconductor substrate having a lower metal wiring layer 111.

The semiconductor substrate may have a particular conduction layer made of a material other than that of the silicon wafer substrate. The conduction layer may be an impurity doped area formed on the semiconductor substrate, a copper wiring layer, or other conductor patterns.

The etch stopping film 112 may be made of a material having high etching selectivity with respect to the interlayer insulation film formed thereon, such as silicon nitride (SiN), silicon carbide (SiC), SiCN, or SiCO. The etch stopping film 112 may have a thickness of 200 through 1000 Å, such as 500 Å.

Then, the interlayer insulation film 113 is formed as a thick layer on the etch stopping film 112. The interlayer insulation film 113 may be a film made of a low dielectric constant material (a low-k insulation layer) such as a porous silicon oxide film, a phosphorous silicate glass(PSG) film, a boron phosphorous silicate glass(BPSG) film, an undoped silicate glass(USG) film, a fluorine doped silicate glass(USG) film, an SIOC film, a high density plasma(HDP) film, a plasma enhanced-tetra ethyl ortho-silicate(PE-TEOS) film, or a spin-on-glass(SOG) film. The interlayer insulation film 113 may have a thickness of 1500 through 15000 Å, such as a thickness of 3000 through 5000 Å.

A photo-resist is deposited on the interlayer insulation film 113 and patterned to open the via-hole portion through a exposure process and a development process, so that a photo-resist pattern 114 is formed.

Then, the interlayer insulation film 113 is removed by using the photo-resist pattern 114 as an etching mask to form a via-hole 116. Accordingly, the etch stopping layer 112 is exposed through the via-hole 116.

As shown in FIG. 3B, an ashing process is performed to remove the photo-resist pattern 114. A dry etching is typically used in the ashing process for removing the photo-resist pattern 114.

The dry etching process may be classified into a method of using a discharge of oxygen plasma and a method of using ozone. In the method of using the oxygen plasma, an oxygen radical, a byproduct of the oxygen plasma, is activated by the photo-resist, an organic material, to generate carbon dioxide. Then, the generated carbon dioxide is discharged by using a vacuum pump to remove the photo-resist. On the other hand, in the method of using ozone, the photo-resist is removed using the strong oxidation effects of the ozone in a high pressure. The ashing process that can be used in the present invention is not limited to those described above, and other various ashing processes can be adopted.

In the aforementioned ashing processes for removing the photo-resist pattern, the photo-resist may be not perfectly removed, and residues or particles 115 may be generated. As shown in FIG. 3C, a cleaning process may be performed to perfectly remove or substantially perfectly remove organic residues, remnants or particles 115 of the photo-resist.

A dry cleaning or a wet cleaning may be performed to remove the residues. If a dry cleaning is performed, oxygen plasma may be used. The dry cleaning using oxygen plasma may be performed with an oxygen flow rate of 500 sccm and a power of 800 W in a pressure of 1500 mT at a temperature of 60 through 80° C. for 20 through 40 minutes. Particles or residues of polymer containing carbon can be effectively removed.

If a wet cleaning is performed, a basic aqueous solution or an acid aqueous solution may be used as a cleaning solution. An oxygenated water H₂O₂ may be used as the basic aqueous solution, and a fluoric acid HF aqueous solution may be used as the acidic aqueous solution. In addition to such an inorganic cleaning, an organic cleaning can be applied. For example, a mixture of 1,1,1-trichloroethane (TCA), which is an organic solvent having excellent solubility, acetone and water may be used. The composition ratio may be adjusted by monitoring a removal state of the photo-resist pattern to optimize the removal rate and performance.

However, the cleaning should be executed without significantly damaging the low-k material. In order to clean the residues 115 of the photo-resist after the ashing process, a cleaning was experimentally performed by spraying a DHF mixture in which pure water and fluoric hydride were mixed with a composition ratio of 100:1 for 12 seconds. As another example, NE14, a typical cleaning solution, was sprayed for 60 seconds. It was observed that the latter example shows relatively less damages to the low-k material than the former example.

Perfectly removing or substantially perfectly removing the residues 115 remained in the ashing process of the photo-resist after forming the via-hole 116 allows the etch stopping film 112 to be appropriately opened, so that a contact between the lower and upper metal wiring layers can be made without failure.

Subsequently, as shown in FIG. 3D, a portion of the etch stopping film 112 exposed through the via-hole 116 is etched to open the lower metal wiring layer 111. Since no particles hinder the etch stopping film 112 from being etched, a portion of the etch stopping film 112 inside of the via-hole 116 can be entirely removed. Then, the organic residues generated in the etching of the etch stopping film 112 are perfectly removed or substantially perfectly removed by an organic cleaning.

As shown in FIG. 3E, the via-hole 116 is filled with a metallic material 117 to provide a via-contact that makes contact with the lower metal wiring layer 111. As a result, the lower metal wiring layer 111 is electrically connected to the upper metal wiring layer through the via-contact. The metallic material may be a material selected from a group comprising Cu, Al, Ag, Au, any metal having low resistivity, or any alloy thereof. Copper is widely used in the art.

A diffuision barrier (not shown) may be provided to prevent diffusion of the metallic material. The diffusion barrier may be a film made of a material selected from a group comprising Ta, TaN, W, WN, Ti, TiN or any combination thereof. The overall thickness may be within a range of 100 through 1000 Å.

After the metallic material is filled, a planarization process is performed to planarize its surface. A chemical mechanical polishing (CMP) method is typically used to planarize the surface. The metallic material deposited on the interlayer insulation film 113 is removed by using the CMP process, and then the metallic material is removed until the interlayer insulation film is exposed. Thus, it is possible to provide a via-contact having a single damascene structure.

Then, another diffusion barrier (not shown) is formed on the resultant product having a via-contact as necessary. The diffuision barrier may be made of SiN, SiC, etc., and may have a thickness within a range between 500 and 1000 Å.

After the via-contact is formed, a metallic material is deposited on the overall surface including the via-contact, and patterned to provide the upper metal wiring layer. Thus, the upper metal wiring layer is electrically connected to the lower metal wiring layer through the via-contact.

Second Exemplary Embodiment

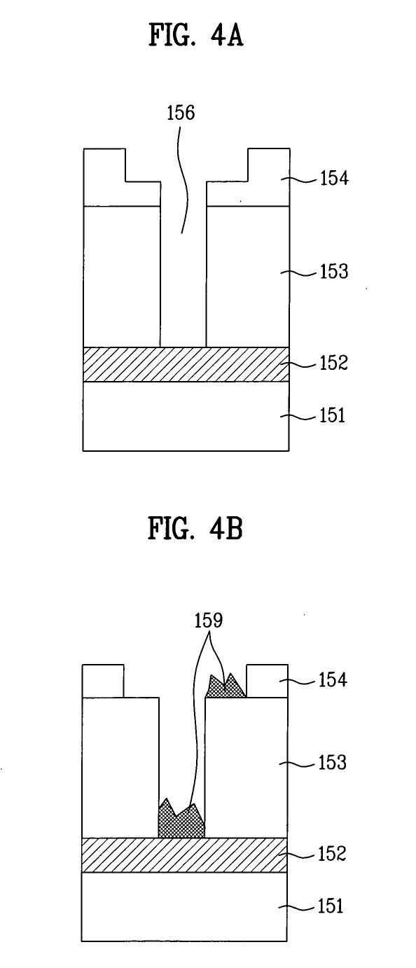

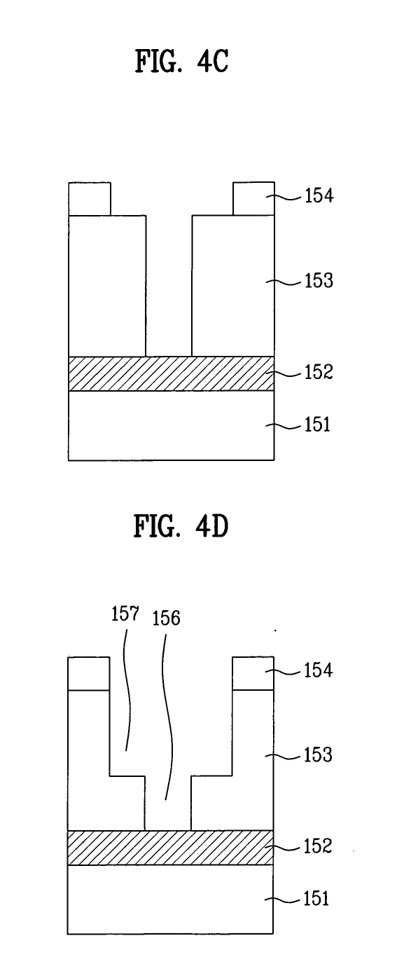

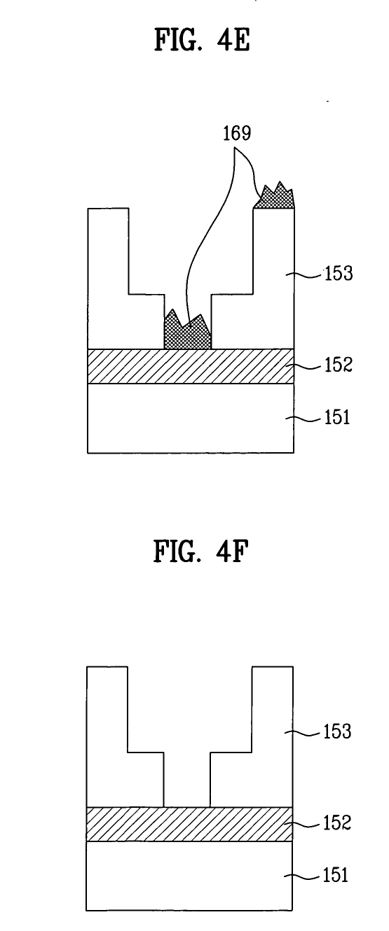

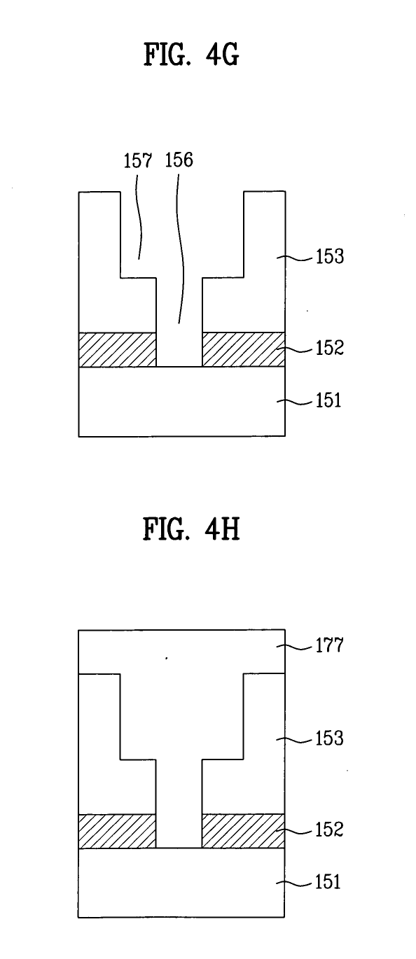

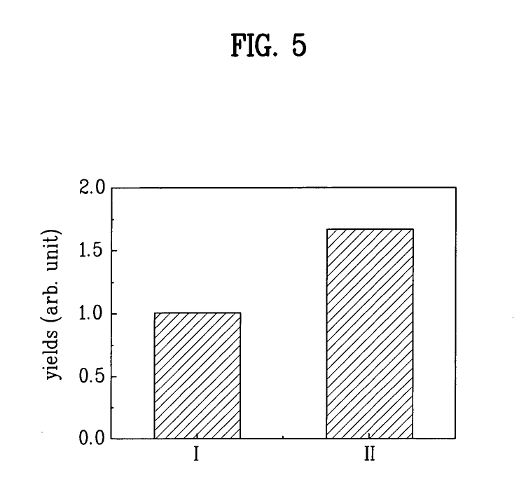

FIGS. 4A-4H are cross-sectional views of a semiconductor device made by a method of forming a metal wiring in a semiconductor device according to a dual damascene process of the present invention.

The second exemplary embodiment relates to a dual damascene process according to the present invention. As shown in FIG. 4A, an etch stopping film 152 may be deposited on a semiconductor substrate having a lower metal wiring layer 151 by using a chemical vapor deposition (CVD) technique.

The semiconductor substrate may have a particular conduction layer made of a material other than that of the silicon wafer substrate. The conduction layer may be an impurity doped area formed on the semiconductor substrate, a copper wiring layer, or other conductor patterns.

The etch stopping film 152 may be made of a material having high etching selectivity with respect to the interlayer insulation film formed thereon, such as silicon nitride (SiN), silicon carbide (SiC), SiCN, or SiCO. The etch stopping film 152 may have a thickness of 200 through 1000 Å, such as 500 Å.

Then, the interlayer insulation film 153 is formed as a thick layer on the etch stopping film 152. The interlayer insulation film 153 may be a film made of a low dielectric constant material (a low-k insulation layer) such as a porous silicon oxide film, a phosphorous silicate glass(PSG) film, a boron phosphorous silicate glass(BPSG) film, an undoped silicate glass(USG) film, a fluorine doped silicate glass(USG) film, an SIOC film, a high density plasma(HDP) film, a plasma enhanced-tetra ethyl ortho-silicate(PE-TEOS) film, or a spin-on- glass(SOG) film. If an applied device is highly integrated, such a low-k insulation layer is preferably provided. The interlayer insulation film 153 may have a thickness of 1500 through 15000 Å, such as a thickness of 3000 through 5000 Å.

A photo-resist is deposited on the interlayer insulation film 153, and then a diffraction lithographic process and a development process is performed to form a photo-resist pattern 154. The photo-resist pattern 154 may be patterned to have a dual step for opening the via-hole portion and have an intermediate step in a trench portion. Remaining regions are retained without change.

Then, the interlayer insulation film 153 is removed by using the photo-resist pattern 154 as an etching mask to form a via-hole 156. Accordingly, the etch stopping layer 152 is exposed through the via-hole 156.

As shown in FIG. 4B, an ashing process is performed until the intermediate step of the photo-resist pattern 154 is removed and the interlayer insulation film 153 is exposed.

In the ashing process for removing the photo-resist pattern 154, the photo-resist may not be perfectly removed and residues or particles 159 may be generated. As shown in FIG. 4C, a cleaning process may be performed to perfectly remove or substantially perfectly remove organic residues, remnants or particles of the photo-resist. A dry cleaning or a wet cleaning may be performed to remove the residues. If a dry cleaning is performed, oxygen plasma may be used. If a wet cleaning is performed, either an organic or inorganic cleaning can be applied.

Then, as shown in FIG. 4D, the interlayer insulation film 153 is etched by using the ashed photo-resist pattern 154 as an etching mask within a predetermined thickness to form a trench 157.

Subsequently, a process of perfectly removing or substantially perfectly removing the remaining photo-resist pattern 154 is performed. The process of removing the photo-resist pattern 154 is usually called an ashing process, and a dry ashing process is typically used. The dry etching process may be classified into a method of using discharge of oxygen plasma and a method of using ozone.

As shown in FIG. 4E, the photo-resist may be not perfectly removed, and residues or particles 169 may be generated.

Accordingly, as shown in FIG. 4F, a cleaning process is executed to perfectly remove or substantially perfectly remove the organic residues, remnants or particles 169 of the photo-resist. For this purpose, either a dry cleaning or a wet cleaning may be performed. Oxygen plasma is usually used for the dry cleaning. In the wet cleaning, either an organic or inorganic cleaning may be applied.

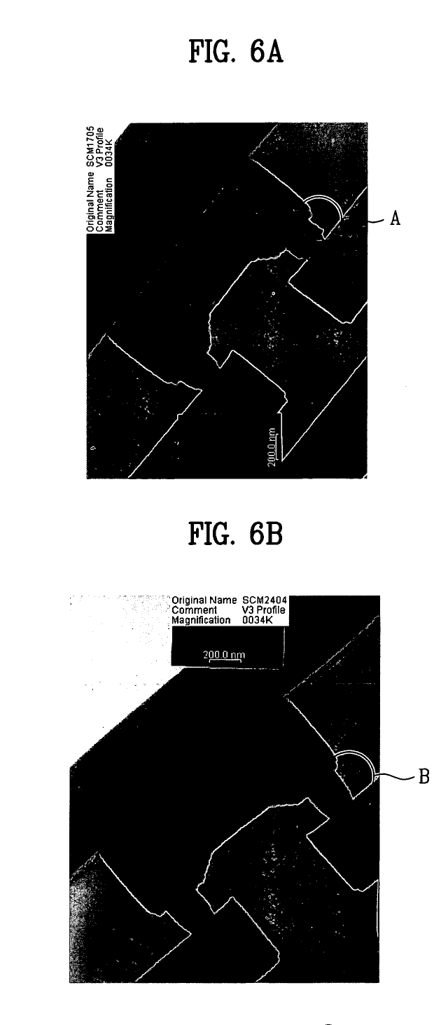

The cleaning should be performed to not significantly damage a low-k material if the low-k material is used in the interlayer insulation film 153. FIGS. 6A and 6B are transmission electron microscope (TEM) photographs showing a dual damascene structure when optimized and unoptimized cleanings are respectively performed for a Cu/low-k device having a thickness of 0.13 μm. In FIG. 6A, a DHF mixture in which pure water and hydrogen fluoride are mixed in a composition ratio of 100:1 is sprayed for 12 seconds to clean out the residues of the remaining photo-resist after the ashing process, and the etch stopping film 152 is etched to open the lower metal wiring layer 151. In FIG. 6B, an NE14 solution, used as a cleaning solution, is sprayed for 60 seconds to clean out the residues of the remaining photo-resist after the ashing process, and the etch stopping film 152 is etched to open the lower metal wiring layer 151.

In the device shown in FIG. 6A, an unoptimized cleaning process is applied so that the low-k insulation layer is over-etched to significantly increase the size of the via-hole (shown as A in FIG. 6A), and the side surface of the low-k insulation layer is roughened. As a result, a barrier metal of the side surface, that is, a diffusion barrier may be inappropriately deposited. On the contrary, in the device shown in FIG. 6B, an optimized cleaning is applied so that the size of the via-hole is appropriately retained along the side surface (shown as B in FIG. 6B).

FIG. 5 is a graph for comparing manufacturing yields of an SRAM having a trench formed according to a related art technique and having a trench formed according to the present invention. In case I of FIG. 5, the etch stopping film is etched to open the lower metal wiring layer without performing a cleaning process after the trench is formed and the photo-resist pattern is ashed. On the contrary, in case II of FIG. 5, a cleaning process is performed to remove residues of the photo-resist after the photo-resist pattern is ashed. Then, the etch stopping film is etched to open the lower metal wiring layer. The manufacturing yield in case II is 60% higher that that of case I. In this embodiment, a Cu/low-k device having a thickness of 0.13 μm has been used.

Subsequently, as shown in FIG. 4G, a portion of the etch stopping film 152 exposed through the via-hole 156 and the trench 157 is etched to open the lower metal wiring layer 151. After the via-hole 156 and the trench 157 are formed, the residues generated in the ashing process of the photo-resist are removed, so that the etch stopping film is appropriately opened. As a result, the lower metal wiring layer 151 can appropriately make contact with the upper metal wiring layer without failure.

As shown in FIG. 4H, the via-hole 156 and the trench 157 are filled with a metallic material 177 to provide a via-contact and an upper metal wiring layer that make contact with the lower metal wiring layer. The lower metal wiring layer is electrically connected to the upper metal wiring layer through the via-contact.

The metallic material 177 may be a material having low resistivity, such as a material selected from a group comprising Cu, Al, Ag, Au, or any alloy thereof. Particularly, copper has been widely used in the art. Since copper is too soft to be adopted in the patterning process, a dual damascene process is preferably applied to simultaneously provide the via-contact and the upper wiring layer.

A diffusion barrier (not shown) may be further provided to prevent diffusion of the metallic material. The diffuision barrier may be a film made of a material selected from a group comprising Ta, TaN, W, WN, Ti, TiN or any combination thereof. The overall thickness may be within a range of 100 through 1000 Å.

After the metallic material is filled, a planarization process is performed to planarize its surface. A chemical mechanical polishing (CMP) method is typically used to planarize the surface. The metallic material deposited on the interlayer insulation film 113 is removed by using the CMP process, and then the metallic material is removed until the interlayer insulation film is exposed. Thus, it is possible to provide a via-contact having a dual damascene structure. As described above, in the dual damascene process, the metal contact hole and the metal wiring are simultaneously formed. Therefore, it is possible to reduce the number of metallic processes.

Then, another diffusion barrier (not shown) is formed on the wiring layer in the dual damascene structure, as necessary. The diffusion barrier may be made of SiN, SiC, etc., and may have a thickness within a range between 500 and 1000 Å.

According to the present invention, residues or particles generated in the photo-resist ashing process after the via-hole and the trench are formed, are perfectly cleaned out and removed. Therefore, the etch stopping film inside the via-hole can be perfectly removed or substantially perfectly removed in the etching process of the etch stopping film for opening the lower wiring layer.

Since residues or particles of the etch stopping film inside the via-hole are perfectly removed or substantially perfectly removed, the lower metal wiring layer can appropriately make contact with the upper metal wiring layer without failure. As a result, it is possible to significantly increase a manufacturing yield.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of forming a metal wiring in a semiconductor device, the method comprising:
forming a lower wiring layer on a semiconductor substrate;
forming an etch stopping film and an interlayer insulation film on an entire surface of the semiconductor substrate including the lower wiring layer;
forming a photo-resist pattern on the interlayer insulation film;
forming a via-hole by using the photo-resist pattern as a mask;
ashing the photo-resist pattern;
cleaning the via-hole;
etching a portion of the etch stopping film exposed through the via-hole to expose the lower wiring layer; and
burying a metallic material in the via-hole to provide a via-contact.

2. The method according to claim 1, wherein cleaning the via-hole comprises wet cleaning or dry cleaning.

3. The method according to claim 1, wherein cleaning the via-hole comprises an organic cleaning or an inorganic cleaning.

4. The method according to claim 1, wherein the via-contact is formed in a single damascene structure.

5. The method according to claim 1, wherein the etch stopping film is made of a material selected from a group consisting of SiN, SiC, SiCN, and SiCO.

6. The method according to claim 1, wherein the metallic material is copper.

7. The method according to claim 1, wherein the interlayer insulation film is made of a low-k insulation material.

8. The method according to claim 1, further comprising a chemical mechanical polishing (CMP) process for planarizing a surface after the via-hole is buried with the metallic material.

9. The method according to claim 1, wherein the photo-resist pattern has a dual step.

10. The method according to claim 9, further comprising:
ashing the photo-resist pattern until an intermediate step portion of the dual step of the photo-resist pattern is substantially perfectly removed, after the process of cleaning the via-hole; and
etching a portion of the interlayer insulation film exposed through the ashed photo-resist pattern to form a trench.

11. The method according to claim 10, further comprising a process of cleaning the trench.

12. The method according to claim 11, wherein the process of cleaning the trench comprises wet cleaning or dry cleaning.

13. The method according to claim 11, wherein the process of cleaning the trench comprises an organic cleaning or an inorganic cleaning.

14. The method according to claim 10, wherein the via-hole is buried with the metallic material to provide the via-contact, and, at the same time, the trench is buried with the metallic material to provide an upper wiring layer.

15. The method according to claim 14, further comprising a chemical mechanical polishing (CMP) process for planarizing a surface after the via-hole and the trench are buried with the metallic material.

16. The method according to claim 14, wherein the via-contact and the upper wiring layer are formed in a dual damascene structure.
